(19) United States
(12) Patent Application Publication
(10) Pub. No.: US 2026/0188608 A1
(43) Pub. Date: Jul. 2, 2026

(54) AUGMENTING SEM IMAGING OUTPUT

(71) Applicant: Applied Materials Israel Ltd., Rehovot (IL)

(72) Inventors: Omri Brand, Rehovot (IL); Ilan Ben-Harush, Tel-Aviv (IL); Erez Lidor, Yavne (IL); David Uliel, Tel-Mond (IL); Sharon Farkash Rainer, Petah-Tikva (IL); Ravid Aber, Tel-Aviv (IL)

(21) Appl. No.: 19/002,496

(22) Filed: Dec. 26, 2024

(51) Int. Cl. H01J 37/22; H01J 37/244; H01J 37/28

(52) U.S. Cl. CPC H01J 37/222; H01J 37/244; H01J 37/28; H01J 2237/1536; H01J 2237/2817

(57) ABSTRACT

The disclosed subject matter relates to a computer system and a computer-implemented method for enhancing Scanning Electron Microscope (SEM) imaging output by mitigating and correcting imaging degradation due to charging distortion effects. The methods and systems presented address artifacts caused by charging distortions, improving the accuracy and reliability of SEM imaging for high-precision semiconductor applications. The solution enables rapid, efficient correction, and can be applied during runtime, such as within a semiconductor SEM scanning sequence, to generate augmented SEM images that facilitate more accurate analysis.

### TECHNICAL FIELD

The presently disclosed subject matter is related to Scanning Electron Microscopy (SEM) imaging of semiconductor specimens, and more specifically to the enhancement of SEM output images.

### BACKGROUND

In semiconductor manufacturing, lithography is a fundamental process used to define intricate patterns on wafers, which are essential for forming electronic circuitries and components. The lithography process typically involves applying a resist layer to the wafer and selectively exposing it to create a precise pattern. Methods such as photolithography, electron beam lithography, and other advanced techniques are employed to achieve this. The outcome is generally a wafer with a patterned resist layer. This patterned layer guides subsequent processing steps, including etching, deposition, and implantation, to form the desired structures in or on the semiconductor material. The precision of the lithography process is critical, as it directly influences the accuracy of the resulting semiconductor structures, thereby impacting device performance and functionality.

Advanced nanoscale lithography (generally referring to features in the nanometer regime) is central in the development of intricate electronic devices. Extreme Ultraviolet (EUV) lithography is a leading technology in this domain that facilitates the production of features such as transistors, interconnects, and other nanoscale elements with exceptional precision. The ability of EUV lithography to define these extremely fine patterns is harnessed for the development of next-generation semiconductors, driving innovation and enhancing device performance.

### General Description

Scanning Electron Microscopy (SEM) is widely used for scanning, inspecting, and measuring dimensions in lithographic processes. At the same time, SEM imaging introduces several disadvantages, including material erosion and charging distortions, which can degrade image quality. When scanning is applied to delicate nanoscale structures, such as those generated by EUV lithography, a high-energy electron beam in SEM can cause erosion of resist structures, altering the patterns. This phenomenon is also known as “shrinkage”, a term that refers to the apparent reduction in size of features due to electron beam damage. Additionally, charge build-up on surfaces of the semiconductor specimen (exhibited significantly on non-conductive surfaces) can cause charging distortion, which may be either linear or non-linear (e.g., parabolic). These distortions affect the accuracy and quality of measurements, manifesting as brightness variations and blurriness. In some instances, charging distortions are referred to as ‘scale’ or ‘scale artifacts,’ as they reflect variations in the relationship between the size of features in the scanned image. The terms ‘scale’ or ‘scale artifacts’ are used herein for the sake of simplicity and clarity. However, the use of these terms should not be construed as limiting the scope of the disclosed subject matter, which encompasses a broader range of distortions that may be characterized by any applicable distortion model. These two factors, shrinkage and charging distortions, may compromise the integrity of the imaging output and may lead to inaccurate measurements.

The presently disclosed subject matter includes a computer system and a computer-implemented method for augmenting SEM imaging output. Specifically, the disclosed methods and systems address and correct degradation in SEM imaging caused by charging distortions. This approach mitigates artifacts resulting from charging distortion, thereby enhancing the accuracy and reliability of the SEM imaging process to meet the increasing precision and accuracy demands of the semiconductor industry. The proposed solution enables rapid and efficient correction and can be implemented during runtime, for example, as part of a semiconductor SEM scanning sequence. This allows for the generation of augmented SEM output images that can be analyzed with greater accuracy.

According to a first aspect of the presently disclosed subject matter there is provided a computer-implemented method for rectifying charging distortions in a set of Scanning Electron Microscope (SEM) output frames of a semiconductor specimen, the method comprising:
receiving a set of frames of the semiconductor specimen, where the set of frames is generated by scanning the specimen using a SEM;
for each frame in the set:
   calculating a scale factor between the frame and a reference image;
   correcting scale of the frame based on the calculated scale factor; and
registering the corrected frames to create a composite image with rectified scale.

In addition to the above features, the method according to this aspect of the presently disclosed subject matter can optionally comprise one or more of features (i) to
i. wherein calculating the scale factor between the frame and the reference frame comprises applying cross-correlation on the frame or a derivative thereof.
ii. wherein cross-correlation includes autocorrelation and wherein calculating the scale factor between the frame and the reference frame comprises:
   projecting the given frame to obtain a respective projected frame;
   applying autocorrelation on the respective projected frame and identifying a respective pitch of the frame according to the highest autocorrelation value; and calculating the scale factor based on a ratio between the respective pitch and a reference pitch of a reference frame.
iii. The method further comprises:
   for a first frame in the set of frames, transforming the projected frame to the frequency domain and identifying the coarse pitch of the given frame according to dominant peak;
   determining a limited search window within the projected frame according to the coarse pitch;
   applying autocorrelation on the given frame within the limited search window.
iv, wherein cross-correlation includes normalized cross-correlation (NCC), and wherein calculating the scale factor between the frame and the reference frame comprises:
   resizing the frame by multiple scale factors, to thereby obtain a collection of scaled versions of the frame, each version being the frame resized by a different scale factor;
   for each of at least part of the collection of versions:
      projecting the version to obtain a projected version;
      applying NCC between the projected version and a projected reference frame (e.g., first frame);
   identifying the scale factor between the frame and the reference frame as the scale factor of a projected version exhibiting the highest NCC value.
v, wherein the semiconductor specimen is characterized by nanoscale features and was produced using EUV lithography.
vi. wherein cross-correlation is autocorrelation and wherein correcting the charging distortions is performed by applying a two-dimensional (2D) autocorrelation analysis across the entire frame, the method comprising:
   applying autocorrelation across the entire image along the x and y axes, either independently or symmetrically, by comparing pixel values along lines across each axis;
   identifying periodicity in one or both dimensions from the autocorrelation analysis to determine scale variations along the x and y axes; and
   correcting the charging distortions based on the identified scale variations, either independently or symmetrically along both axes, to rectify charging distortions in the 2D image.
vii. wherein cross-correlation is Normalized Cross-Correlation (NCC) and wherein correcting the charging distortions comprises applying a two-dimensional (2D) Phase Correlation Algorithm to detect and adjust for scale and alignment differences, the method comprising:
   transforming both the frame and a reference image into the Fourier domain to isolate phase information and generate a 2D correlation map showing correlation values across x and y shifts;
   identifying the initial peak in the 2D correlation map to indicate the best alignment and scale for the frame, including cases of independent or symmetric scaling along both axes;
   applying a 2D parabolic fit around the peak for sub-pixel accuracy in determining the optimal alignment; and
   extracting the final scaling factors, either independently or symmetrically along both axes, based on the refined peak position, to achieve precise alignment and correct charging distortions.
viii. The method further comprises scanning the semiconductor specimen using a SEM to obtain the set of frames.
ix. The method further comprises executing the method in run-time as part of a SEM scanning sequence to thereby generate augmented SEM output images.

According to a second aspect of the presently disclosed subject matter there is provided a computer system configured and operable to execute a method according to the first aspect.

According to a third aspect of the presently disclosed subject matter there is provided a non-transitory computer readable medium comprising instructions that, when executed by a computer, cause the computer to perform a method according to the first aspect.

The presently disclosed subject matter further contemplates a computer program product comprising instructions which, when the program is executed by a computer, cause the computer to carry out a method according to the first aspect.

The presently disclosed subject matter further contemplates an examination system dedicated for examining semiconductor specimens, e.g., as part of a semiconductor manufacturing process, the system comprising a Scanning Electron Microscope (SEM) and at least one processing circuitry, wherein the SEM is configured to scan a semiconductor specimen and generate SEM output images of the semiconductor specimen or part thereof, and the at least one processing circuitry is configured to receive the scanned images and execute a method for rectifying charging distortions in the SEM output images as described with respect to the first aspect above.

The system, the non-transitory program storage device, the computer program product, and the examination system disclosed above, can optionally comprise one or more of features (i) to (ix) listed above, mutatis mutandis, in any technically possible combination or permutation.

### BRIEF DESCRIPTION OF THE DRAWINGS

In order to understand the presently disclosed subject matter and to see how it may be carried out in practice, the subject matter will now be described, by way of non-limiting examples only, with reference to the accompanying drawings, in which:

FIG. 1 shows an example of an SEM image of a line pattern that exhibits artifacts in line width caused by charging distortion (A), and the image being rectified (B), as further disclosed below.

FIG. 2 is a graph plotting the lines of a semiconductor pattern along the x-axis and the respective measured line width of each line as measured using an SEM.

FIG. 3 illustrates a generalized block diagram of an examination system, in accordance with certain examples of the presently disclosed subject matter.

FIG. 4a and FIG. 4b each illustrate a block diagram of an SEM output augmentation module, in accordance with certain examples of the presently disclosed subject matter.

FIG. 5 is a high-level flowchart showing the principal operations performed as part of an SEM output augmentation process, in accordance with an example of the presently disclosed subject matter.

FIG. 6 is a flowchart of operations showing a specific implementation of an SEM output augmentation process, in accordance with an example of the presently disclosed subject matter.

FIG. 7 is a flowchart of operations carried out as part of coarse pitch calculation, in accordance with certain examples of the presently disclosed subject matter.

FIG. 8 is a flowchart of operations carried out as part of fine pitch calculation, in accordance with certain examples of the presently disclosed subject matter.

FIG. 9 is a flowchart of operations showing another specific implementation of an SEM output augmentation process, according to one example of the presently disclosed subject matter.

### DETAILED DESCRIPTION

A Scanning Electron Microscope (SEM) produces grayscale images by scanning a sample with a focused beam of high-energy electrons using electromagnetic lenses. As the beam scans across the surface of the sample, it interacts with the atoms, leading to the emission of secondary electrons and backscattered electrons.

The detection of secondary electrons, emitted from atoms near the surface, allows for high-resolution imaging of the sample's topography. Backscattered electrons, which are primary electrons scattered from the sample atoms, provide information on composition and contrast based on atomic number differences within the sample. Detectors designed for specific types of emissions capture these emissions, and the collected data is then processed to produce a grayscale image, indicating the quantity of electrons captured by the detector. The number of collected electrons varies, depending on the surface topography, composition, or other properties of the sample. SEMs generate highly detailed grayscale images of the sample surface at magnification levels unattainable with traditional optical microscopes, providing precise inspection and measurement capabilities during the manufacturing of semiconductor wafers.

As mentioned above, however, applying SEM scanning to semiconductor specimens, particularly those with nanoscale structures, such as those generated in EUV lithography, can cause shrinkage and charge buildup, which may lead to inaccurate measurements.

These problems intensify in semiconductor metrology, where SEM is often used with multiple scans to enhance measurement accuracy. This approach involves repeatedly scanning the same area of a semiconductor sample, and combining data from these multiple passes into a composite image to improve the signal-to-noise ratio, thus producing more accurate and reliable dimensional measurements of critical semiconductor features (“critical dimensions”), such as transistor gate lengths, line widths, and layer thicknesses. Each successive scan contributes to the cumulative electron dose received by the sample. This increased exposure can lead to incremental damage or alterations caused by shrinkage and/or charge buildup, thus further degrading the imaging output, and, consequently, the measurements.

Mitigating the issues of shrinkage and charge build-up during SEM operation includes applying an optimize working point that defines certain scanning parameters. For example, by carefully selecting and adjusting the landing energy, it is possible to reduce thermal stress and material deformation, thereby reducing shrinkage. At the same time, managing landing energy can help control the accumulation of static charges on the sample.

However, optimizing landing energy to address one problem can exacerbate the other. Lower landing energies, (e.g., in the range of 100 volts to 300 volts) are effective in reducing thermal stress and thus shrinkage. Nevertheless, these low energies can lead to increased charge build-up, especially in non-conductive samples, as fewer electrons are available to neutralize static charges. Conversely, increasing the landing energy allows more electrons to reach the sample surface, helping to dissipate charge build-up, but at the cost of introducing more thermal energy, which heightens the risk of shrinkage. Furthermore, the working point in SEM scanning involves multiple variables, and it can be challenging to find a set of values that satisfies all requirements while also reducing charging distortions. Even at higher landing energies (e.g., 500 volts or greater), charging issues may persist, indicating that adjustments to landing energy alone are often insufficient. Balancing these variables to achieve optimal imaging quality without distortion requires careful tuning and may still fall short of fully mitigating charging distortions.

When using SEM to measure semiconductor patterns, especially lines, it is crucial to maintain the critical dimension (CD) consistent across the entire Field of View (FOV) of the SEM to ensure precision and accuracy in measurements and the overall quality of semiconductor devices. The FOV is the observable area that an SEM can image at a given time. In the context of a line pattern, CD refers to the width of the smallest line or the space between lines in a semiconductor pattern, and its consistency is important for device performance and reliability, as variations can lead to defects that impact electrical properties.

Charging distortion artifacts, resulting from charge build-up, challenge the consistency of CD across the entire FOV. As a result of charging distortion, CD measured at certain areas of the FOV, commonly at the FOV edges, may appear smeared or otherwise distorted, resulting in inaccurate measurements. This smearing results from the overlaying of multiple images, each exhibiting a different scaling factor and consequentially different pitch values, thus causing misalignment between the lines in different images.

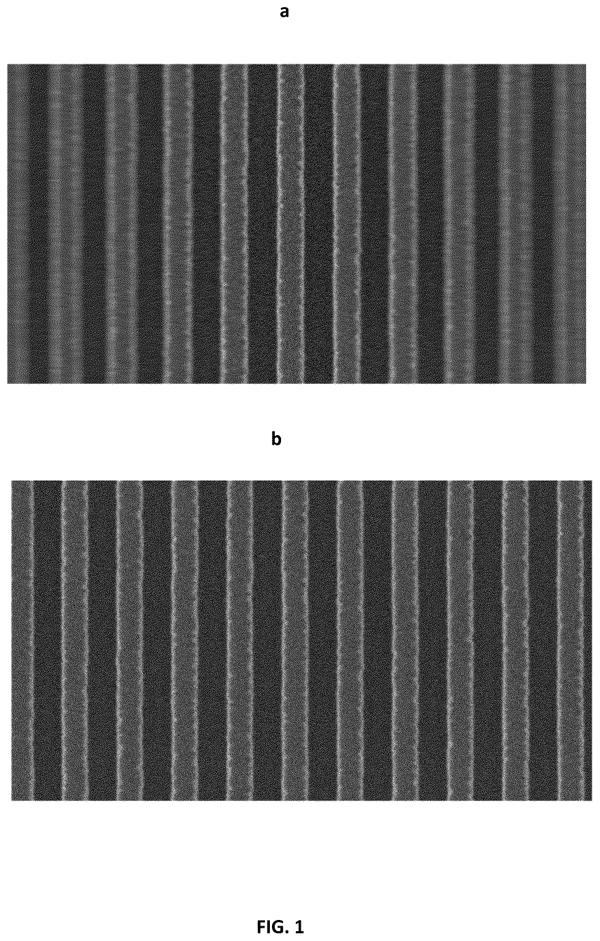

FIG. 1-A shows an example of an SEM image of a line pattern that exhibits artifacts in line width caused by charging distortion. FIG. 1-B shows the image in FIG. 1-A after being rectified, as further disclosed below. Each line is the area between two white lines, with each pair of lines separated by a non-conductive area (black). As seen in FIG. 1-A, lines located at the edges of the field of view (FOV) appear smeared.

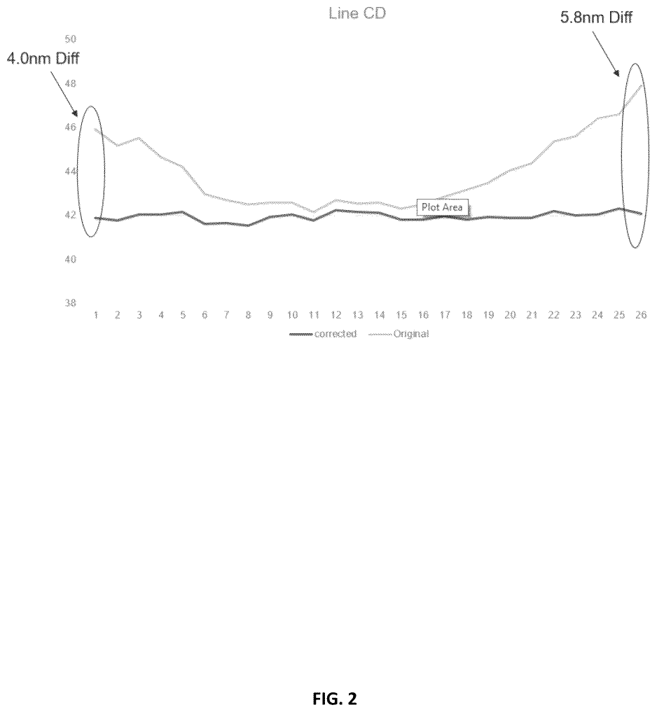

FIG. 2 is a graph plotting the lines of a semiconductor pattern along the x-axis and the respective line width of each line measured using an SEM. The upper line extended horizontally represents the distorted measurements of the SEM output, as demonstrated in FIG. 1-A, and exhibits a parabola-like shape due to increased line width measurements in lines located at the edges of the FOV. The lower horizontal line represents the rectified SEM output, as demonstrated in FIG. 1-B and exhibits generally uniform values across all lines, where small inconsistencies are due to noise.

One advantage of the presently disclosed subject matter is in increasing consistency of pitch values across all lines in the field of view (FOV) in different images, each generated by scanning the same semiconductor specimen (or part thereof). Pitch is the center-to-center distance between two consecutive and identical features, such as lines, trenches, or any repetitive structural elements on a semiconductor wafer. By mitigating charging distortion artifacts and obtaining uniform pitch in different images, high quality and sharp SEM images can be obtained. From these images accurate measurements of critical dimensions (CD) can be attained, including both the width of the lines and the width of the spaces between them.

Another advantage of the presently disclosed subject matter is in increasing the consistency of CD measurements for a given semiconductor specimen performed at different working points. This includes obtaining accurate and consistent average pitch at different working points, where each working point may be assigned with a different landing energy (e.g., 150 volts, 300 volts, and 500 volts).

During various stages of the semiconductor fabrication process, specimens may be measured at different working points. By rectifying charging distortion, it is possible to achieve consistent pitch across all images. This method can be applied to images obtained at different working points, ensuring uniform pitch measurements across various operating conditions.

Yet another advantage of the presently disclosed subject matter is determining or estimating frame 0. “Frame 0” refers to a theoretical reference frame that exists without any actual scanning performed on a specimen. Since no scan has been conducted on Frame 0, it is free from any damage or alterations that might occur during the scanning process. It represents the pristine state of the specimen before any scanning-induced damage or changes.

Correcting charging distortion cannot eliminate all variations between working points due to differences introduced in the initial scan. Estimating Frame 0 for each working point helps calibrate the frames and reduces bias caused by the differing charging regimes across working points.

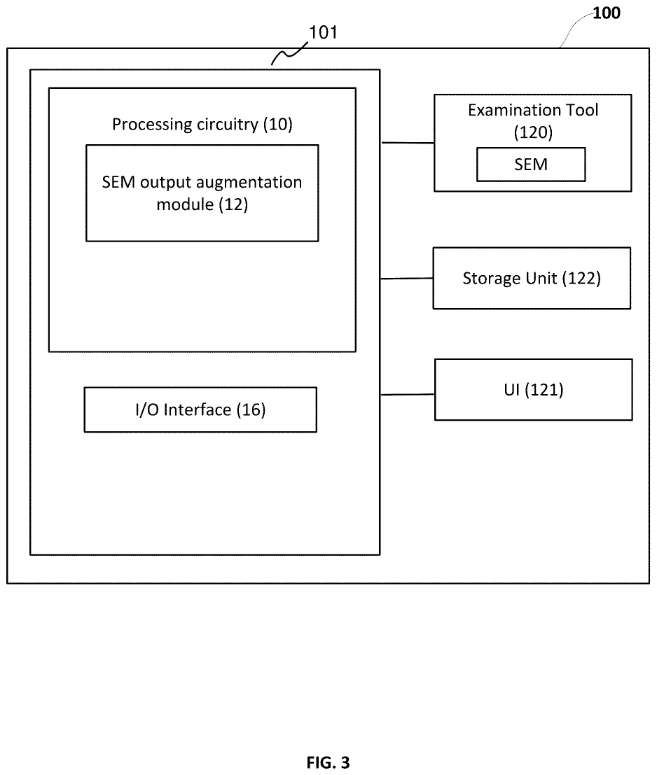

Attention is drawn to FIG. 3, which is a generalized block diagram illustration of a computer system 101 configured with SEM augmentation capabilities according to examples of the presently disclosed subject matter. FIG. 3 shows a non-limiting example where system 101 is integrated in a semiconductor examination system 100. In other examples system 101 and 100 can be separated, possibly located at different locations and operatively connectible over a communication link.

Examination system 100 can be used for examination of a semiconductor specimen (e.g., a wafer, a die, or parts thereof) e.g., as part of the specimen fabrication process. The examination referred to herein can be construed to include any kind of operations related to inspection of semiconductor specimens including the inspection/detection of defects, defect classification, segmentation, metrology operations, etc., with respect to the specimen.

System 100 can comprise one or more examination tools 120 configured to scan a specimen and capture images thereof to be further processed for various examination applications. The term “examination tool” used herein should be construed to cover any tools that can be used in examination-related processes. The examination tools 120 include, for example, one or more inspection tools and/or one or more review tools that generate grayscale output images of an examined semiconductor specimen (e.g., by scanning or imaging). An inspection tool is configured to scan a specimen (e.g., an entire wafer, an entire die, or portions thereof) to capture inspection images (typically, at a relatively high-speed and/or low-resolution) for various purposes such as measuring CDs and/or detecting defects. Examination tool 120 includes a Scanning Electron Microscope (SEM).

Review and inspection tools are central in semiconductor examination. Inspection tools scan the wafer to identify defects, while review tools provide detailed, high-resolution analysis of these specific areas at a slower speed. This ensures precise quality control. The tools may be separate or combined into one tool with different operating modes, such as SEM, capable of providing both low- and high-resolution images.

Per the illustrated example, computer system 101 comprises processing circuitry 10 configured to execute various processing operations. This includes processing images of a semiconductor specimen (e.g., a wafer, a die, or parts thereof) generated by an examination tool 120, including an SEM.

Processing circuitry 10 can comprise one or more processors and one or more memories (not shown). In some examples, the processing circuitry is configured to execute one or more functional modules according to computer-readable instructions implemented on a non-transitory computer-readable memory included in the processing circuitry. These functional modules are hereinafter referred to as being comprised in the processing circuitry.

By way of example, the functional modules may include an SEM output augmentation module 12 configured to process SEM output images of a semiconductor specimen. More specifically, a plurality of SEM output images generated by the scanning of the same semiconductor specimen can be received and processed to remove charging distortion artifacts. The processed images are combined to provide an enhanced aggregated image of the semiconductor specimen.

According to some examples, system 100 can comprise or be otherwise operatively connected to a data storage unit 122. Data storage unit 122 can be configured to store any data necessary or otherwise related to the operation of system 100 and/or 101, including for example computer software which is loaded during execution of any one of the modules described above, intermediate processing results generated by system 100 and/or 101, SEM output images, enhanced aggregated images generated by output augmentation module 12, etc.

In some examples, system 100 and/or system 101 can optionally comprise a user interface 121 to enable user interaction with system 100 and/or system 101. The user interface can include a display device, user interaction devices (e.g., computer mouse and keyboard) and a graphical user interface (GUI) configured to enable, inter alia, user-specified inputs related to system 100 and/or 101. For instance, the user may view on the display the processing results or intermediate processing results, such as, e.g., SEM output images, contact hole images, enhanced aggregated images generated by output augmentation module 12, etc.

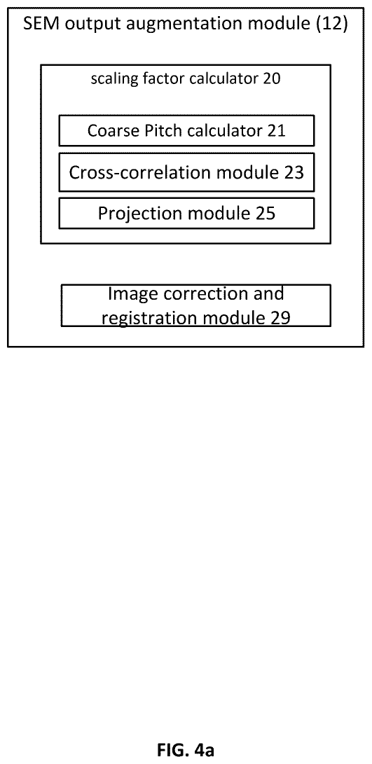

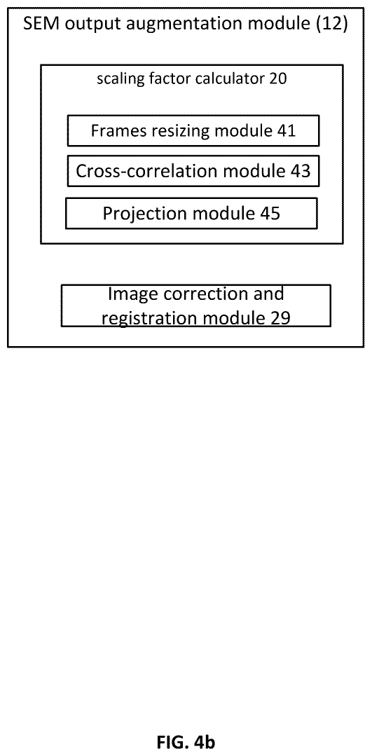

FIG. 4a and FIG. 4b are block diagrams each showing an example of a more detailed view of various components of SEM output augmentation model module 12. These components include a scaling factor calculator 20 and image correction and registration module 29. According to the example shown in FIG. 4a, components of scaling factor calculator 20 include coarse pitch calculator 21, cross-correlation module 23, and projection module 25. According to the example shown in FIG. 4b, components of scaling factor calculator 20 include frames resizing module 41, cross-correlation module 43, and projection module 45. Operations performed by each of the components listed above are described below with reference to the following figures.

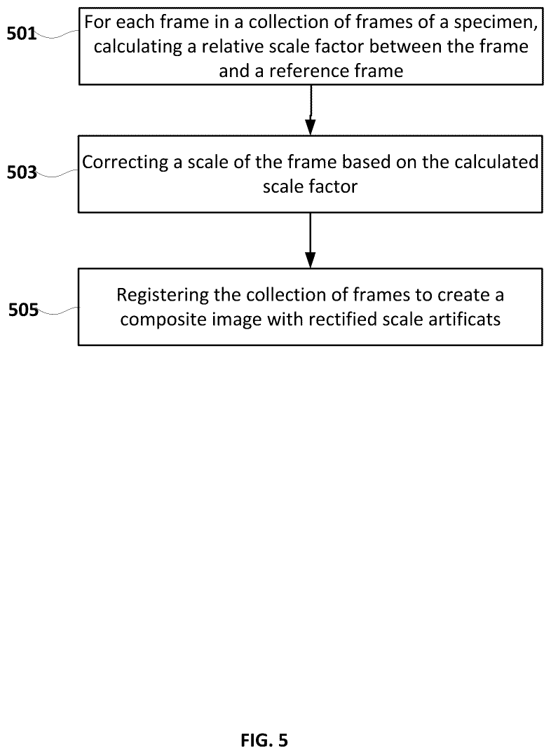

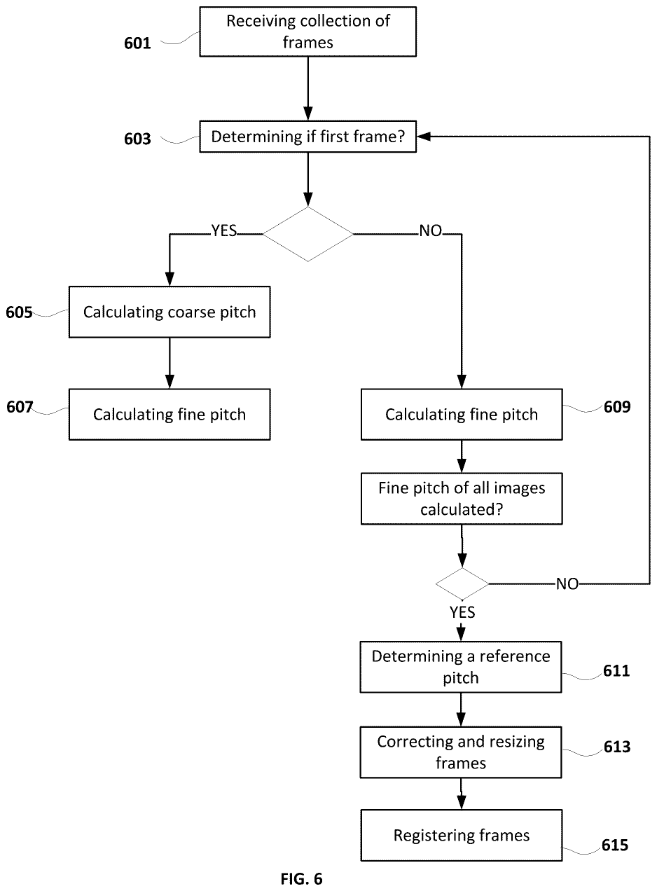

Turning to FIG. 5, this shows a high-level flowchart of operations carried out as part of an SEM output augmentation process, according to an example of the presently disclosed subject matter. Operations described with reference to FIG. 5 (as well as FIGS. 6, 7, 8, and 9 described below) are described for clarity and by way of example only with reference to output augmentation module 12 and its components.

A set of SEM output images (frames) which were generated by scanning a certain semiconductor specimen by a SEM multiple times, is obtained and processed. In some examples, the semiconductor specimen can include nanoscale lithography, generated for example by EUV technology, thus being highly susceptible to charging distortion artifacts.

In some examples, the SEM is configured to generate images in a manner that minimizes or reduces shrinkage caused by the scanning process. This involves selecting specific working points with operational parameters that reduce damage caused during scanning of the specimen.

During processing a relative scaling factor is calculated for each of the images (or frames) in the set (501). In some examples, processing is applied on the images sequentially according to the order of image generation. In some examples, SEM output augmentation module 12 comprises a scaling factor calculator 20 configured to execute operations dedicated for calculating a charging distorting factor, as described below.

The calculated scaling factor is used for correcting (resizing) the frames in the set, to obtain a set of rectified frames with substantially uniform pitch (block 503).

The rectified frames are registered to create together a composite image of the semiconductor specimen with rectified charging distortion artifacts, thus enhancing its quality (block 505). In some examples, SEM output augmentation module 12 comprises an image correction and registration module 29 configured to apply the calculated factor for correcting the frame and registering the corrected frames.

FIG. 6 is a flowchart of operations showing a specific implementation of an SEM output augmentation process, according to one example of the presently disclosed subject matter.

A set of SEM output images which were generated by scanning a certain semiconductor specimen by an SEM multiple times is obtained and processed (601).

For the first frame generated in the set (by the first scan of the SEM over the specimen), coarse pitch is calculated (605). Coarse pitch calculation involves determining an approximate value for the distance between repetitive features (pitch) in an image, such as lines. According to this example, calculator 20 may include a coarse pitch calculator 21 configured for calculating coarse pitch.

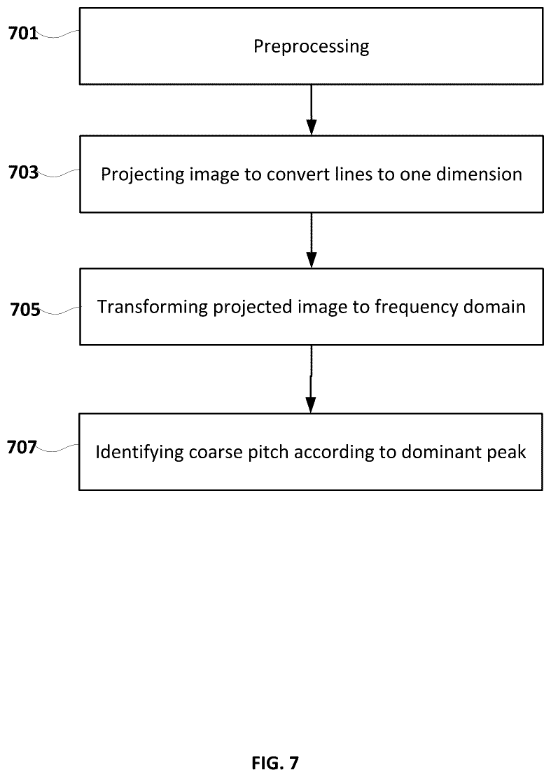

FIG. 7 is a flowchart showing operations carried out as part of the determination of coarse pitch in block 605, according to some examples. Preprocessing, comprising normalization and noise reduction, is applied on the first frame (block 701). Considering that the image exhibits a line pattern which consists of parallel lines spaced at regular intervals, the image is projected in the x direction to improve throughput (by reducing the overall amount of data to be processed) and SNR (block 703; e.g., by projection module 25). Projection can be implemented in various ways including for example, averaging the y values, selecting a minimal/maximal value, selecting k a minimal/maximal value, and preforming any of the previous operations in any angle, or by any other technique of linear or non-linear dimensionality reduction (manifold learning).

The projected image is transformed from spatial domain to the frequency domain, e.g., by applying the Fast Fourier Transform on the projected image (block 705; e.g., by projection module 25). The FFT produces a spectrum where peaks indicate the presence of periodic structures. The coarse pitch is identified according to the dominant peak (block 707). For a line pattern, the most prominent peak represents the dominant frequency of the line spacing, which is inversely related to the pitch in the spatial domain.

Reverting to FIG. 6, once the coarse pitch is known, it is used for determining a fine pitch in the first image (block 607). In some examples, this is done by applying autocorrelation, which measures the similarity of a signal or image with itself over different shifts, revealing repeating patterns, consistency, or distortions.

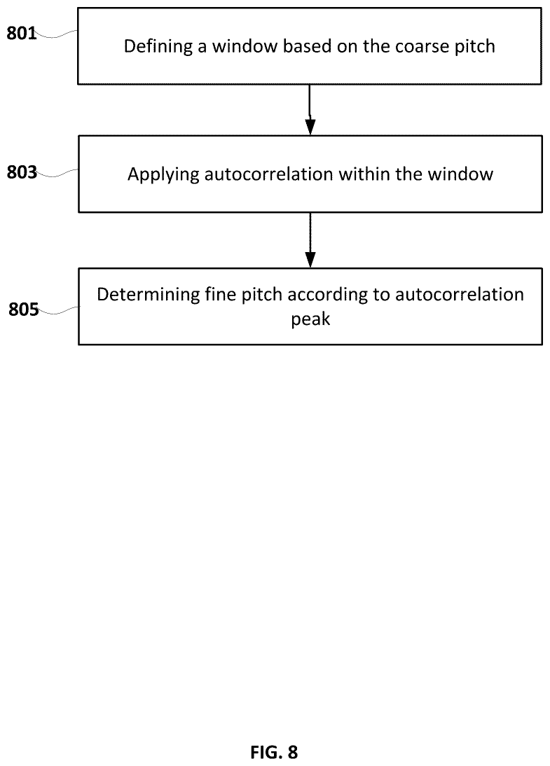

FIG. 8 is a flowchart showing operations carried out as part of fine pitch calculation, according to some examples. Calculator 20 may further include cross-correlation module 23 configured executing operations described with reference to FIG. 8. The coarse pitch can be used, for example, to define a window around the expected pitch value for the autocorrelation computation (block 801). This window should be wide enough to account for possible deviations, but narrow enough to reduce unnecessary calculations. Thus, if the coarse pitch is estimated to be P units, define a window from P-A to P+A, where A is a small range to cover potential variations. Calculating coarse pitch and using a limited window reduces computational complexity by focusing the fine pitch computation on the relevant range, thereby improving efficiency.

Autocorrelation of the projected signal is applied within the limited window defined by the coarse pitch (block 803), and the peak of the resulting autocorrelation function is identified. The position of this peak corresponds to the refined pitch estimate in the first image (block 805). This peak position represents the distance over which the pattern in the signal repeats, thereby providing an estimate of the pitch and effectively measuring the periodicity of the signal or image within the defined window.

Reverting to block 603 in FIG. 6, for the following frames in the set of frames, for each frame the same coarse pitch can be applied as in the first image, and accordingly it is not necessary to repeat its calculation. The fine pitch is calculated as described above with respect to the first frame.

Once pitch values of all frames in the set are obtained, a reference pitch is determined to be used for all subsequent images for charging distortion correction (block 611). One example of a reference pitch is the fine pitch calculated for the first image. Another example is an average fine pitch of all frames. This requires first calculating the fine pitch of all frames, followed by calculating an average pitch value, and then using the average pitch value as a reference pitch for correcting charging distortion.

The reference pitch is used for correcting charging distortion and resizing each frame in the set of frames (block 613). In some examples, for each frame a respective scaling factor is calculated based on its respective pitch calculated for the frame and the reference pitch. Assuming the first frame serves as the reference frame, the scaling factor of the first frame and second frame S_{1,2} is calculated by the ratio of the pitch of the reference image P₁ and the pitch of the second image P₂:

$${S}_{1 , 2} = \frac{{P}_{1}}{{P}_{2}}$$

Once calculated, the resulting scaling factor S_{1,2} is used for correcting the second image by resizing the pitch in the second image according to the calculated scaling factor.

For the third frame, the scaling factor is determined using the reference pitch S₁, by:

$${S}_{1 , 3} = \frac{{P}_{1}}{{P}_{3}}$$

The third image is then resized according to the calculated charging distortion. This process is repeated for all frames in the set of frames.

If, for example, P₁ is 0.5 mm/pixel (reference pitch) and Pₙ is 0.6 mm/pixel, the second frame is resized by a scaling factor of

$$\frac{0.5}{0.6} = 0.833$$

After resizing, all images should have the same or very similar pitch, ensuring consistent alignment across the entire set.

Usually the process of image rescaling involves sub pixel interpolation. This involves interpolation methods that allow for resizing images with sub-pixel precision, such as Gaussian or parabolic fitting, bilinear interpolation, and bicubic interpolation. In some examples, SEM output augmentation module 20 includes sub-pixel alignment and scaling capabilities, enabling to account for minimal distortions.

Once the pitch of all frames in the set of frames has been corrected, the frames are registered to create the final composite image of the semiconductor specimen with rectified charging distortion artifacts (block 615). As shrinkage affects CD but does not change pitch, the above approach is invariant to shrinkage. In some examples, operations described with reference to blocks 611 to 615 are executed by image correction and registration module 29.

Notably, in alternative examples, coarse pitch is not calculated, e.g., when coarse pitch is known from prior knowledge. According to this approach, the process may include:
Preprocessing as explained above with reference to block 701, projecting images in the x direction as explained above with refence to block 703. Applying transformation and autocorrelation on the projected image and finding the highest autocorrelation score which is indicative of the scale.

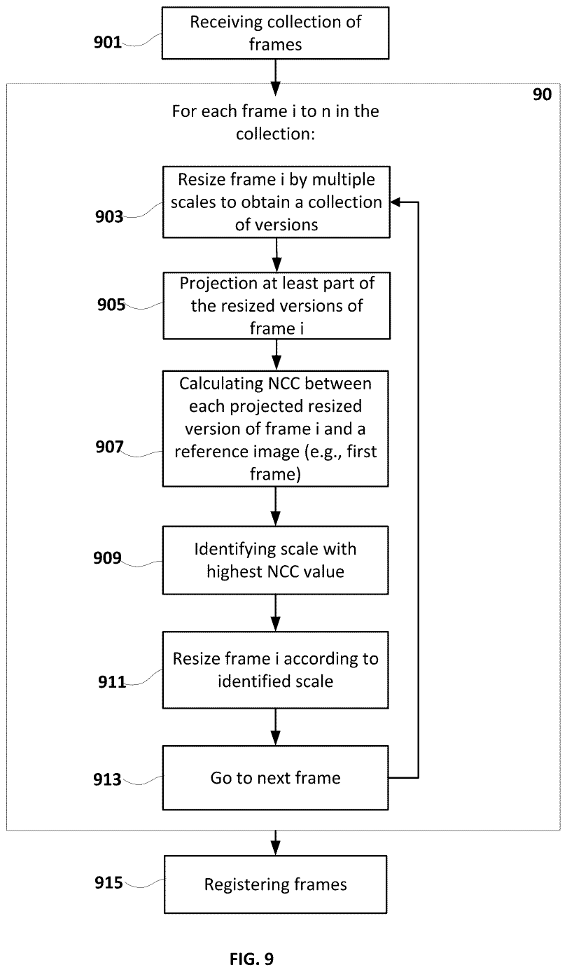

Proceeding to FIG. 9, this shows another example of operations performed to generate enhanced SEM output images. Notably, unlike the calculations described above with reference to FIGS. 6 and 8, where a repeating pattern is a prerequisite, the following process is also applicable to non-repetitive patterns.

A set of SEM output images (n frames), generated by scanning a semiconductor specimen multiple times with an SEM, is obtained (901). In one example, where the first frame is used as the reference frame, processing starts with the second frame (i=2). In another example, where the reference frame is calculated based on the average pitch of all images, processing starts with the first frame (i=1).

The first frame that is processed (hereinafter “current frame”) undergoes the following processing operations:
The current frame is resized by multiple charging distortions (903; e.g., by frame resizing module 41). By resizing a frame by multiple charging distortions incrementally, several derivatives of the current frame (referred to herein as “versions”) of the same image are created, each version resized slightly differently, resulting in an image characterized by a different pitch. Resizing can be implemented, for example, using various methods such as nearest-neighbor, bilinear, or bicubic interpolation. The range of the charging distortions applied for resizing can vary.

Each version of the current frame is projected in the x-direction (905; e.g., by projection module 45), and normalized cross-correlation (NCC) is applied between a projected reference image (e.g., first image) and a projection of the version (907; e.g., by cross-correlation module 43).

The version of the current frame that results in the highest NCC value, indicating the best alignment with the reference image, is identified, and the respective scaling factor of the version is selected (block 909). The current frame is resized according to the selected scaling factor (block 911).

The process proceeds to the processing of the next frame (i.e., new current frame) in the set of frames (i+1), which undergoes the same processing (block 913).

Once the pitch of all frames in the set of frames has been corrected, the frames are registered to create the final composite image of the semiconductor specimen with rectified charging distortion artifacts (block 915). Correction and registration can be executed by image correction and registration module 49.

In some cases, projecting data to one-dimension (1D) is either not feasible or yields poor-quality data, especially in complex two-dimensional (2D) images where patterns do not align along a single axis and exhibit significant variations in both dimensions. In such 2D images, a simple 1D projection is not suitable to accurately assess and correct distortions.

To address this limitation, the principles for correcting charging distortions in 1D can be extended to a comprehensive 2D analysis. For example, in 2D images where distinct repeating features may not be present, scale variations along both the x and y axes can still be assessed by applying autocorrelation across the entire image. This method detects periodic structures or regularities across the x and y dimensions, even in complex patterns, allowing for the identification and correction of charging distortions in 2D images.

Considering the example described with reference to FIGS. 6, 7, and 8, a similar process can be applied where the projection step described in block 703 is omitted. Instead, autocorrelation is applied across the entire image, where, for each x-coordinate, pixels along the entire line of y-values are compared. This means that for a fixed x-position, the image is shifted horizontally, and the correlation between pixels along all y-values is calculated at each shift. This sliding comparison along the x-axis captures the repetition of patterns across the entire y-dimension for each horizontal shift. For each y-coordinate, a similar process is performed by comparing pixels along the entire line of x-values. Here, the image is shifted vertically, and the correlation between pixels along all x-values is calculated for each vertical shift. This captures the repetition of patterns across the entire x-dimension for each shift along the y-axis.

This 2D analysis can be implemented using the Phase Correlation Algorithm, which leverages the Fourier transform and cross-power spectrum to detect and correct translation, scaling, and rotation differences between images. By transforming both images into the Fourier domain, the algorithm isolates phase information, enabling the precise detection of subtle distortions with sub-pixel accuracy. This approach allows for a comprehensive correction of charging distortions, ensuring consistent scaling across the entire image.

In some examples, after applying the Phase Correlation Algorithm, a 2D correlation map is generated, showing correlation values across x and y shifts to indicate optimal alignment. The initial peak in this map reveals the best scale or shift for alignment. For sub-pixel accuracy, a 2D parabolic fit is applied around this peak, refining the exact location. Finally, the coordinates of the refined peak are used to extract the final scaling factors (or translation values) needed for precise alignment.

Considering the example described with reference to FIG. 9, a similar process can be applied with the following differences:
Resizing of the frames, as described with reference to block 903, can be performed independently along the x-axis and the y-axis. Horizontal scaling adjusts the width of the image, stretching or compressing it along the x-axis while leaving the y-axis unchanged. Similarly, vertical scaling adjusts the height of the image, stretching or compressing it along the y-axis without affecting the x-axis. If both axes require the same scaling factor, a uniform resizing can be applied to both axes simultaneously.
Projection according to block 905 is not performed. For each version of a given frame iii, Normalized Cross-Correlation (NCC) is applied between a reference image (e.g., the first image) and each version. The scale with the highest NCC value is identified, and the corresponding scale factor for that version is selected. The current frame is then resized according to this selected scale factor, as described with reference to block 911. The process then continues as outlined in blocks 913 and 915.

Those versed in the art will readily appreciate that the teachings of the presently disclosed subject matter are not bound by the system illustrated in FIGS. 3, 4a and b. Each system component and module in FIGS. 3, 4a and 4b can be made up of any combination of software, hardware, and/or firmware, as relevant, executed on a suitable device or devices, which perform the functions as defined and explained herein. Equivalent and/or modified functionality, as described with respect to each system component and module, can be consolidated or divided in another manner. Thus, in some embodiments of the presently disclosed subject matter, the system may include fewer, more, modified, and/or different components, modules, and functions than those shown in FIGS. 3, 4a and 4b.

Each component in FIGS. 3, 4a and 4b may represent one or more instances of the same component. These instances may operate independently or cooperatively to process various data and electrical inputs and enable operations associated with a computerized examination system. Multiple instances of a component may be employed for purposes such as improving performance, ensuring redundancy, enhancing availability, or supporting specific functionality. For example, certain portions of a component's functionality may be allocated across different instances of the component.

While certain examples of the present disclosure refer to a processing circuitry being configured to perform the above-recited operations, the functionalities/operations of the aforementioned modules can be performed by the one or more processors in the processing circuitry in various ways. By way of example, the operations of each module can be performed by a specific processor, or by a combination of processors. The operations of the various modules, such as processing the examination/inspection image, and performing defect examination, etc., can thus be performed by respective processors (or processor combinations), while, optionally, these operations may be performed by the same processor. The present disclosure should not be limited to being construed as one single processor always performing all the operations. The present disclosure should not be construed as limiting the described operations to being performed exclusively by a single processing circuitry. These multiple processing circuitries may operate independently or collaboratively, with interoperability, enabling communication, data exchange, and task sharing to achieve the described functionalities.

The systems illustrated in FIGS. 1a and 1b can be implemented in a distributed computing environment, in which one or more of the aforementioned components shown in FIGS. 1a and 1b can be distributed over several local and/or remote devices. By way of example, training module 117 can be located at the same entity (in some cases hosted by the same device) or on a different device located at a different location.

In some examples, certain components utilize a cloud implementation, e.g., are implemented in a private or public cloud. Communication between the various components of the examination system, in cases where they are not located entirely in one location or in one physical entity, can be realized by any signaling system or communication components, modules, protocols, software languages, and drive signals, and can be wired and/or wireless, as appropriate.

Unless specifically stated otherwise, as apparent from the above discussions, it is appreciated that, throughout the specification, discussions utilizing terms such as “obtaining”, “receiving”, “calculating”, “correcting”, “registering” or the like, include an action and/or processes of a computer that manipulate and/or transform data into other data, said data represented as physical quantities, e.g. such as electronic quantities, and/or said data representing the physical objects.

The terms “computer”, “computer system”, “computer device”, “computerized device”, “computerized system” or the like used herein, should be expansively construed to include any kind of hardware-based electronic device with one or more data processing circuitries. Each processing circuitry can comprise, for example, one or more processors operatively connected to computer memory, capable of executing stored instructions to perform the operations described herein. Any reference made in the description or claims to a processing circuitry should be construed to optionally include also multiple processing circuitries.

The one or more processors referred to herein can represent one or more general-purpose processing devices such as a microprocessor, a central processing unit, or the like. More particularly, a given processor may be one of a complex instruction set computing (CISC) microprocessor, a reduced instruction set computing (RISC) microprocessor, a very long instruction word (VLIW) microprocessor, a processor implementing other instruction sets, or a processor implementing a combination of instruction sets. The one or more processors may also be one or more special-purpose processing devices such as an application-specific integrated circuit (ASIC), a field programmable gate array (FPGA), a digital signal processor (DSP), a graphics processing unit (GPU), a network processor, or the like.

It is appreciated that certain features of the presently disclosed subject matter, which are, for clarity, described in the context of separate embodiments, may also be provided in combination in a single embodiment. Conversely, various features of the presently disclosed subject matter, which are, for brevity, described in the context of a single embodiment, may also be provided separately, or in any suitable sub-combination.

It will also be understood that the system according to the presently disclosed subject matter may be a suitably programmed computer. Likewise, the presently disclosed subject matter contemplates a computer program being readable by a computer for executing the method of the presently disclosed subject matter. The presently disclosed subject matter further contemplates a machine-readable (e.g., non-transitory) memory tangibly embodying a program of instructions executable by the machine for executing the method of the presently disclosed subject matter.

It is to be understood that the presently disclosed subject matter is not limited in its application to the details set forth in the description contained herein or illustrated in the drawings. The presently disclosed subject matter is capable of other embodiments and of being practiced and carried out in various ways. Hence, it is to be understood that the phraseology and terminology employed herein are for the purpose of description and should not be regarded as limiting. As such, those skilled in the art will appreciate that the conception upon which this disclosure is based may readily be utilized as a basis for designing other structures, methods, and systems for carrying out the several purposes of the present presently disclosed subject matter.

1. A computer-implemented method for rectifying charging distortions in a set of Scanning Electron Microscope (SEM) output frames of a semiconductor specimen, the method comprising:
receiving a set of frames of the semiconductor specimen, where the set of frames is generated by scanning the specimen using an SEM;
for each frame in the set:
calculating a scale factor between the frame and a reference image;
correcting charging distortions of the frame based on the calculated scale factor; and
registering the corrected frames to create a composite image with rectified charging distortions.

2. The computer-implemented method of claim 1, wherein calculating the scale factor between the frame and the reference frame comprises applying cross-correlation on the frame or a derivative thereof.

3. The computer-implemented method of claim 2, wherein cross-correlation includes autocorrelation and wherein calculating the scale factor between the frame and the reference frame comprises:
projecting the given frame to obtain a respective projected frame;
applying autocorrelation on the respective projected frame and identifying a respective pitch of the frame according to the highest autocorrelation value; and
calculating the scale factor based on a ratio between the respective pitch and a reference pitch of a reference frame.

4. The computer-implemented method of claim 3, further comprising:
for a first frame in the set of frames, transforming the projected frame to the frequency domain and identifying coarse pitch of the given frame according to dominant peak;
determining a limited search window within the projected frame according to the coarse pitch;
applying the autocorrelation on the given frame within the limited search window.

5. The computer-implemented method of claim 2, wherein cross-correlation includes normalized cross-correlation (NCC), and wherein calculating the scale factor between the frame and the reference frame comprises:
resizing the frame by multiple scale factors, to thereby obtain a collection of scaled versions of the frame, each version being the frame resized by a different scale;
for each of at least part of the collection of versions:
projecting the version to obtain a projected version;
applying NCC between the projected version and a projected reference frame;
identifying the scale factor between the frame and the reference frame as the scale factor of a projected version exhibiting highest NCC value.

6. The computer-implemented method of claim 1, wherein the semiconductor specimen is characterized by nanoscale features and was produced using EUV lithography.

7. The computer-implemented method of claim 2, wherein cross-correlation is autocorrelation, and wherein correcting the charging distortions is performed by applying a two-dimensional (2D) autocorrelation analysis across the entire frame, the method comprising:
applying autocorrelation across the entire image along the x and y axes, either independently or symmetrically, by comparing pixel values along lines across each axis;
identifying periodicity in one or both dimensions from the autocorrelation analysis to determine scale variations along the x and y axes; and
correcting the charging distortions based on the identified scale variations, either independently or symmetrically along both axes, to rectify charging distortions in the 2D image.

8. The computer-implemented method of claim 2, wherein cross-correlation is Normalized Cross-Correlation (NCC) and wherein correcting the charging distortions comprises applying a two-dimensional (2D) Phase Correlation Algorithm to detect and adjust for charging distortions and alignment differences, the method comprising:
transforming both the frame and a reference image into the Fourier domain to isolate phase information and generate a 2D correlation map showing correlation values across x and y shifts;
identifying the initial peak in the 2D correlation map to indicate the best alignment and scale for the frame, including cases of independent or symmetric scaling along both axes;
applying a 2D parabolic fit around the peak for sub-pixel accuracy in determining the optimal alignment; and
extracting the final scaling factors, either independently or symmetrically along both axes, based on the refined peak position to achieve precise alignment and correct charging distortions.

9. The computer-implemented method of claim 1 further comprising scanning the semiconductor specimen using a SEM.

10. The computer-implemented method of claim 9 comprising executing the method in run-time as part of a SEM scanning sequence to thereby generate augmented SEM output images.

11. A computer system for rectifying charging distortions in Scanning Electron Microscope (SEM) output frames of a semiconductor specimen, the system comprising:
processing circuitry configured to:
receive a set of frames of the semiconductor specimen, wherein the set of frames is generated by scanning the specimen using an SEM;
for each frame in the set:
calculate a scale factor between the frame and a reference image;
correct the charging distortions of the frame based on the calculated scale factor;
and
register the corrected frames to create a composite image with rectified charging distortions.

12. The computer system of claim 11, wherein the processing circuitry calculates the scale factor between the frame and the reference frame by applying cross-correlation on the frame or a derivative thereof.

13. The computer system of claim 12, wherein cross-correlation includes autocorrelation, and wherein the processing circuitry is configured for calculating the scale factor by calculating a pitch of the frame, to:
project the given frame to obtain a respective projected frame;
apply autocorrelation on the respective projected frame and identify a respective pitch of the frame according to the highest autocorrelation value; and
calculate the scale factor based on a ratio between the respective pitch and a reference pitch of a reference frame.

14. The computer system of claim 13, wherein the processing circuitry is further configured to:
transform the projected frame of a first frame in the set to the frequency domain and identify a coarse pitch of the given frame according to a dominant peak;
determine a limited search window within the projected frame according to the coarse pitch; and
apply autocorrelation on the given frame within the limited search window.

15. The computer system of claim 12, wherein cross-correlation includes normalized cross-correlation (NCC), and wherein the processing circuitry is configured for calculating the scale factor between the frame and the reference frame, to:
resize the frame by multiple scale factors, thereby obtaining a collection of scaled versions of the frame, where each version represents the frame resized by a different scale;
for each of at least part of the collection of versions:
project the version to obtain a projected version; and
apply NCC between the projected version and a projected reference frame;
identify the scale factor between the frame and the reference frame as the scale factor of a projected version exhibiting the highest NCC value.

16. The computer system of claim 11, wherein the semiconductor specimen is characterized by nanoscale features and was produced using EUV lithography.

17. The computer system of claim 12, wherein cross-correlation is autocorrelation, and wherein the processing circuitry is configured for correcting the charging distortions by applying a two-dimensional (2D) autocorrelation analysis across the entire frame, to:
apply autocorrelation across the entire image along the x and y axes, either independently or symmetrically, by comparing pixel values along lines across each axis;
identify periodicity in one or both dimensions from the autocorrelation analysis to determine scale variations along the x and y axes; and
correct the charging distortions based on the identified scale variations, either independently or symmetrically along both axes, to rectify charging distortions in the 2D image.

18. The computer system of claim 12, wherein cross-correlation is Normalized Cross-Correlation (NCC), and wherein the processing circuitry is configured for correcting the charging distortions by applying a two-dimensional (2D) Phase Correlation Algorithm to detect and adjust for scale and alignment differences, to:
transform both the frame and a reference image into the Fourier domain to isolate phase information and generate a 2D correlation map showing correlation values across x and y shifts;
identify the initial peak in the 2D correlation map to indicate the best alignment and scale for the frame, including cases of independent or symmetric scaling along both axes;
apply a 2D parabolic fit around the peak for sub-pixel accuracy in determining the optimal alignment; and
extract the final scaling factors, either independently or symmetrically along both axes, based on the refined peak position to achieve precise alignment and correct charging distortions.

19. The computer system of claim 11, further comprising a Scanning Electron Microscope (SEM) configured to scan the semiconductor specimen and generate the set of frames.

20. A non-transitory computer-readable medium comprising instructions that, when executed by a computer, cause the computer to perform a method of rectifying charging distortions in a set of Scanning Electron Microscope (SEM) output frames of a semiconductor specimen, the method comprising:
receiving a set of frames of the semiconductor specimen, wherein the set of frames is generated by scanning the specimen using an SEM;
for each frame in the set:
calculating a scale factor between the frame and a reference image;
correcting the scale of the frame based on the calculated scale factor; and
registering the corrected frames to create a composite image with rectified scale.
